(19) United States
(12) Patent Application Publication
(10) Pub. No.: US 2025/0005739 A1
(43) Pub. Date: Jan. 2, 2025

(54) SYSTEMS AND METHODS FOR DEFECT DETECTION AND DEFECT LOCATION IDENTIFICATION IN A CHARGED PARTICLE SYSTEM

(71) Applicant: ASML Netherlands B.V., Veldhoven (NL)

(72) Inventors: Shengcheng JIN, San Jose, CA (US); Lingling PU, San Jose, CA (US); Liangjiang YU, Pleasanton, CA (US)

(73) Assignee: ASML Netherlands B.V., Veldhoven (NL)

(21) Appl. No.: 18/710,127

(22) PCT Filed: Oct. 18, 2022
(86) PCT No.: PCT/EP2022/078928

§ 371 Date: May 14, 2024

Related U.S. Application Data
(60) Provisional application No. 63/264,142, filed on Nov. 16, 2021.

(51) Int. Cl. G06T 7/00; G06T 3/14; G06T 5/60; H01J 37/22; H01J 37/28

(52) U.S. Cl. CPC G06T 7/001; G06T 3/14; G06T 5/60; H01J 37/222; H01J 37/28; G06T 2207/10061; G06T 2207/20081; G06T 2207/30148; H01J 2237/221; H01J 2237/2817

(57) ABSTRACT

Apparatuses, systems, and methods for providing beams for defect detection and defect location identification associated with a sample of charged particle beam systems. In some embodiments, a method may include obtaining an image of a sample; determining defect characteristics from the image; generating an updated image based on the determined defect characteristics and the image; and aligning the updated image with a reference image.

### CROSS-REFERENCE TO RELATED APPLICATIONS

This application claims priority of U.S. application 63/264,142 which was filed on 16 Nov. 2021 and which is incorporated herein in its entirety by reference.

### FIELD

The description herein relates to the field of charged particle beam systems, and more particularly to systems and methods for defect detection and defect location identification associated with a sample of charged particle beam system inspection systems.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for defect detection and defect location identification associated with a sample of charged particle beam systems. In some embodiments, a method may include obtaining an image of a sample; determining defect characteristics from the image; generating an updated image based on the determined defect characteristics and the image; and aligning the updated image with a reference image.

In some embodiments, a non-transitory computer readable medium that stores a set of instructions that is executable by at least one processor of a computing device may cause the computing device to perform a method for image analysis comprising obtaining an image of a sample; determining defect characteristics from the image; generating an updated image based on the determined defect characteristics and the image; and aligning the updated image with a reference image.

In some embodiments, a system may include a controller including circuitry configured to cause the system to perform obtaining an image of a sample; determining defect characteristics from the image; generating an updated image based on the determined defect characteristics and the image; and aligning the updated image with a reference image.

In some embodiments, a method may include obtaining an image of a sample; mapping the image to a defect-free image; generating an updated image based on the mapping and the image; and aligning the updated image with a reference image.

In some embodiments, a method may include obtaining an image of a sample; training a machine learning model to map the image to a defect-free image; generating an updated image by applying the machine learning model to the image; and aligning the updated image with a reference image.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary multi-beam system that is part of the exemplary charged particle beam inspection system of FIG. 1, consistent with embodiments of the present disclosure.

FIG. 3 is an exemplary graph showing a yield rate of secondary electrons relative to landing energy of primary electron beamlets, consistent with embodiments of the present disclosure.

FIG. 4 is a schematic diagram illustrating an exemplary a voltage contrast response of a wafer, consistent with embodiments of the present disclosure.

FIG. 5 is a schematic diagram illustrating image restoration and defect detection of a sample, consistent with embodiments of the present disclosure.

FIG. 6 illustrates a flowchart representing an exemplary method of image analysis.

FIG. 7 illustrates a flowchart representing an exemplary method of image analysis, consistent with embodiments of the present disclosure.

FIG. 8 is a schematic diagram of a system for defect detection and defect location identification, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed at the proper location. If the structure is defective, then the process can be adjusted so the defect is less likely to recur. Defects may be generated during various stages of semiconductor processing. For the reason stated above, it is important to find defects accurately, efficiently, and as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

For example, voltage contrast inspection may be used as an early proxy for electric yield associated with a sample. SEM images including voltage contrast patterns typically show a random occurrence of failures associated with features of a sample (e.g., varying grey scale levels of features). For example, grey level intensity levels in an SEM inspection image may deviate from grey level intensity levels in a defect-free SEM image, thereby indicating that a sample associated with the SEM inspection image includes one or more defects (e.g., electrical open or short failures). In some embodiments, other characteristics (e.g., besides or in addition to voltage contrast characteristics) in an SEM inspection image may deviate from a defect-free SEM image (e.g., characteristics related to line-edge roughness, line-width roughness, local critical dimension uniformity, necking, bridging, edge placement errors, etc.), thereby indicating that a sample associated with the SEM inspection image includes one or more defects.

A system may perform a distortion correction on a SEM inspection image and align the SEM inspection image with a template image to detect one or more defects on an inspected sample. For example, one or more defects on the inspected sample may be detected by comparing the aligned SEM images to a plurality of reference images (e.g., comparing an inspection image to two defect-free images of a sample during die-to-die inspection).

However, even after performing a distortion correction on a SEM inspection image, image analysis during inspection suffers from constraints. Because a sample may have many defects, a SEM inspection image may differ greatly from a template SEM image, resulting in misalignment of the SEM inspection image and the template image.

Moreover, a plurality of reference images may be used to detect one or more defects under an assumption that defects occur randomly and rarely, thereby reducing the possibility that the reference images include the same defects as the inspection image. However, it is not uncommon for reference images to include the same defects as the inspection image. When reference images include defects (e.g., the same defects as the inspection image or other defects), a system may fail to identify real defects in the inspection image or the system may fail to use characteristics of the inspection image (e.g., physical features such as bridges) due to noisy data.

Due to misalignment of the inspection image and the template image, systems are not able to accurately identify or index locations of defects on a sample (e.g., image analysis algorithms may fail during image alignment).

Some of the disclosed embodiments provide systems and methods that address some or all of these disadvantages by identifying regions of an inspection image that may be restored and using the identified regions to detect one or more defects in the inspection image. Some disclosed embodiments may restore an inspection image to a defect-free image by calculating defect-free characteristics for the inspection image and applying the calculated defect-free characteristics to the inspection image. In some embodiments, a system may restore the inspection image to a defect-free image by mapping the inspection image to a defect-free image and applying the mapping to the inspection image. In some embodiments, a system may restore the inspection image to a defect-free image by training a machine learning model to map the obtained inspection image to a defect-free image and applying the machine learning model to the inspection image. Systems may align the restored inspection image with a template image to identify one or more locations of the restored inspection image at which restoration was performed and index one or more locations of defects on a sample.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

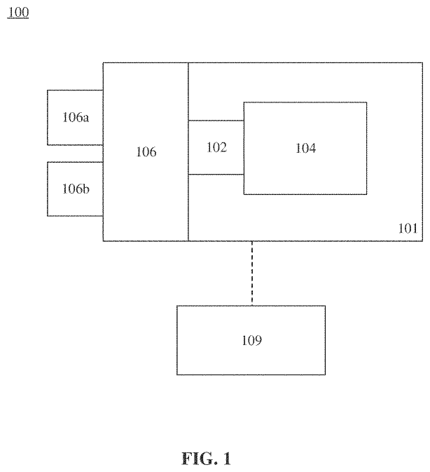

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

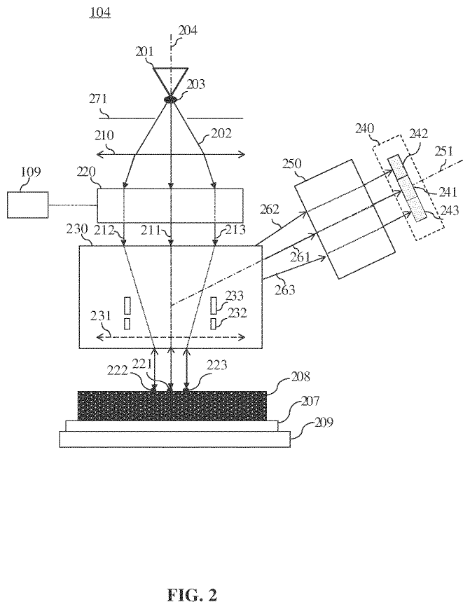

Reference is now made to FIG. 2, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principal plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 overtime depending on the steps of scanning process.

Although FIG. 2 shows that apparatus 104 uses three primary electron beams, it is appreciated that apparatus 104 may use two or more number of primary electron beams. The present disclosure does not limit the number of primary electron beams used in apparatus 104. In some embodiments, apparatus 104 may be a SEM used for lithography.

Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries. adapting to different throughputs and resolution requirements.

A non-transitory computer readable medium may be provided that stores instructions for a processor (e.g., processor of controller 109 of FIGS. 1-2) to carry out image processing, data processing, beamlet scanning, database management, graphical display, operations of a charged particle beam apparatus, or another imaging device, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

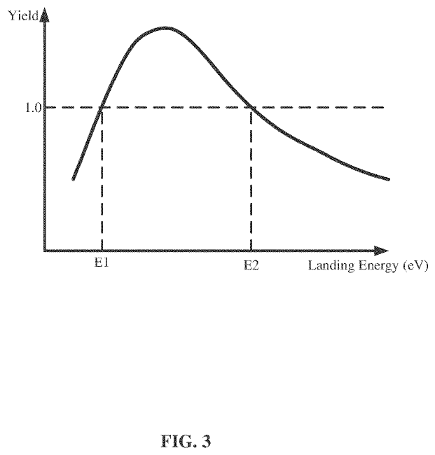

FIG. 3 illustrates an exemplary graph showing a yield rate of secondary electrons relative to landing energy of primary electron beamlets, consistent with embodiments of the present disclosure. The graph illustrates the relationship of the landing energy of a plurality of beamlets of a primary electron beam (e.g., plurality of beamlets 211, 212, or 213 of primary electron beam 202 of FIG. 2) and the yield rate of secondary electron beams (e.g., secondary electron beams 261, 262, or 263 of FIG. 2). The yield rate indicates the number of secondary electrons that are produced in response to the impact of the primary electrons. For example, a yield rate greater than 1.0 indicates that more secondary electrons may be produced than the number of primary electrons that have landed on the wafer. Similarly, a yield rate of less than 1.0 indicates that fewer secondary electrons may be produced in response to the impact of the primary electrons.

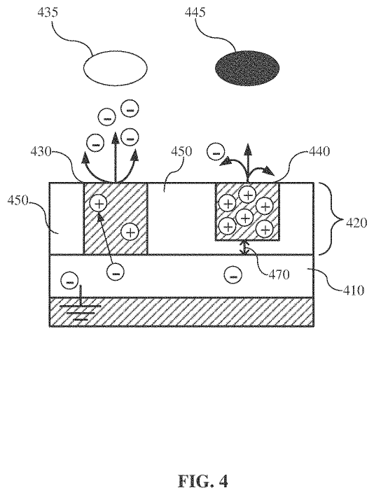

As shown in the graph of FIG. 3, when the landing energy of the primary electrons is within a range from E₁ to E₂, more electrons may leave the surface of the wafer than land onto the surface of the wafer, which may result in a positive electrical potential at the surface of the wafer. In some embodiments, defect inspection may be performed in the foregoing range of landing energies, which is called “positive mode.” An electron beam tool (e.g., electron beam tool 104 of FIG. 2) may generate a darker voltage contrast image of a device structure with a more positive surface potential since a detection device (e.g., detection device 240 of FIG. 2) may receive fewer secondary electrons (see FIG. 4).

When the landing energy is lower than E₁ or higher than E₂, fewer electrons may leave the surface of the wafer, thereby resulting in a negative electrical potential at the surface of the wafer. In some embodiments, defect inspection may be performed in this range of the landing energies, which is called “negative mode.” An electron beam tool (e.g., electron beam tool 104 of FIG. 2) may generate a brighter voltage contrast image of a device structure with a more negative surface potential a detection device (e.g., detection device 240 of FIG. 2) may receive more secondary electrons (see FIG. 4).

In some embodiments, the landing energy of the primary electron beams may be controlled by the total bias between the electron source and the wafer.

FIG. 4 illustrates a schematic diagram of a voltage contrast response of a wafer, consistent with embodiments of the present disclosure. In some embodiments, physical and electrical defects in a wafer (e.g., resistive shorts and opens, defects in deep trench capacitors, back end of line (BEOL) defects, etc.) can be detected using a voltage contrast method of a charged particle inspection system. Defect detection using voltage contrast images may use a pre-scanning process (i.e., a charging, flooding, neutralization, or prepping process), where charged particles are applied to an area of the wafer (e.g., sample 208 of FIG. 2) to be inspected before conducting the inspection.

In some embodiments, an electron beam tool (e.g., electron beam tool 104 of FIG. 2) may be used to detect defects in internal or external structures of a wafer by illuminating the wafer with a plurality of beamlets of a primary electron beam (e.g., plurality of beamlets 211, 212, or 213 of primary electron beam 202 of FIG. 2) and measuring a voltage contrast response of the wafer to the illumination. In some embodiments, the wafer may comprise a test device region 420 that is developed on a substrate 410. In some embodiments, test device region 420 may include multiple device structures 430 and 440 separated by insulating material 450. For example, device structure 430 is connected to substrate 410. In contrast, device structure 440 is separated from substrate 410 by insulating material 450 such that a thin insulator structure 470 (e.g., thin oxide) exists between device structure 440 and substrate 410.

The electron beam tool may generate secondary electrons (e.g., secondary electron beams 261, 262, or 263 of FIG. 2) from the surface of test device region 420 by scanning the surface of test device region 420 with a plurality of beamlets of a primary electron beam. As explained above, when the landing energy of the primary electrons is between E₁ and E₂ (i.e., the yield rate is greater than 1.0 in FIG. 3), more electrons may leave the surface of the wafer than land on the surface, thereby resulting in a positive electrical potential at the surface of the wafer.

As shown in FIG. 4, a positive electrical potential may build-up at the surface of a wafer. For example, after an electron beam tool scans test device region 420 (e.g., during a pre-scanning process), device structure 440 may retain more positive charges because device structure 440 is not connected to an electrical ground in substrate 410, thereby resulting in a positive electrical potential at the surface of device structure 440. In contrast, primary electrons with the same landing energy (i.e., the same yield rate) applied to device structure 430 may result in fewer positive charges retained in device structure 430 since positive charges may be neutralized by electrons supplied by the connection to substrate 410.

An image processing system (e.g., controller 109 of FIG. 2) of an electron beam tool may generate voltage contrast images 435 and 445 of corresponding device structures 430 and 440, respectively. For example, device structure 430 is shorted to the ground and may not retain built-up positive charges. Accordingly, when primary electron beamlets land on the surface of the wafer during inspection, device structure 430 may repel more secondary electrons thereby resulting in a brighter voltage contrast image. In contrast, because device structure 440 has no connection to substrate 410 or any other grounds, device structure 440 may retain a build-up of positive charges. This build-up of positive charges may cause device structure 440 to repel fewer secondary electrons during inspection, thereby resulting in a darker voltage contrast image.

An electron beam tool (e.g., multi-beam electron beam tool 104 of FIG. 2) may pre-scan the surface of a wafer by supplying electrons to build up the electrical potential on the surface of the wafer. After pre-scanning the wafer, the electron beam tool may obtain images of multiple dies within the wafer. Pre-scanning is applied to the wafer under the assumption that the electrical surface potential built-up on the surface of the wafer during pre-scanning will be retained during inspection and will remain above the detection threshold of the electron beam tool.

However, the built-up surface potential level may change during inspection due to the effects of electrical breakdown or tunneling, thereby resulting in failure to detect defects. For example, when a high voltage is applied to a high resistance thin device structure (e.g., thin oxide), such as an insulator structure 470, leakage current may flow through the high resistance structure, thereby preventing the structure from functioning as a perfect insulator. This may affect circuit functionality and result in a device defect. A similar effect of leakage current may also occur in a structure with improperly formed materials or a high resistance metal layer, for example a cobalt silicide (e.g., CoSi, CoSi₂, Co₂Si, Co₃Si, etc.) layer between a tungsten plug and a source or drain area of a field-effect transistor (FET).

A defective etching process may leave a thin oxide resulting in unwanted electrical blockage (e.g., open circuit) between two structures (e.g., device structure 440 and substrate 410) intended to be electrically connected. For example, device structures 430 and 440 may be designed to make contact with substrate 410 and function identically, but due to manufacturing errors, insulator structure 470 may exist in device structure 440. In this case, insulator structure 470 may represent a defect susceptible to a breakdown effect.

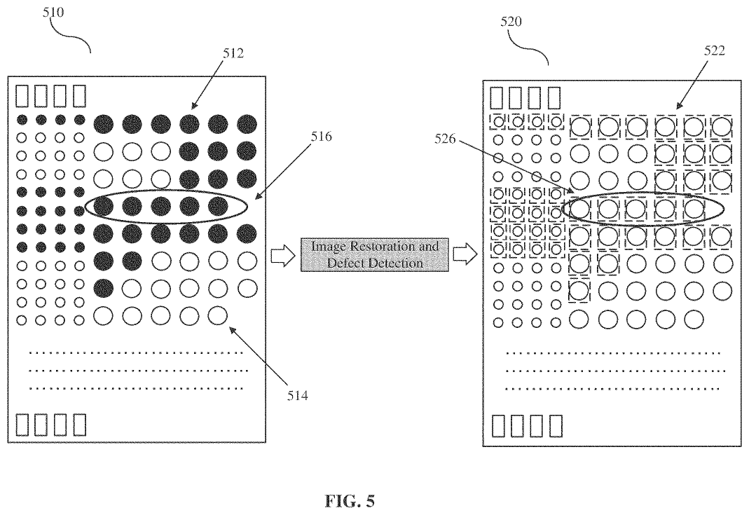

FIG. 5 is a schematic diagram illustrating image restoration and defect detection of a sample, consistent with embodiments of the present disclosure.

In some embodiments, a system may obtain an inspection image 510 of a sample (e.g., a SEM image generated during inspection of a sample). In some embodiments, inspection image 510 may include one or more regions of a sample (e.g., sample 208 of FIG. 2) in a field of view (FOV). Inspection image 510 may include one or more defects 512. In some embodiments, defects in an inspection image may have certain intensity levels (e.g., levels of “brightness” or “darkness” grey levels of voltage contrast images) that are different from defect-free characteristics. While defect 512 is illustrated as a “dark” feature, it should be understood that defects may be illustrated as various grey levels or other characteristics (e.g., line-edge roughness, line-width roughness, local critical dimension uniformity, necking, bridging, edge placement errors, holes, broken lines, etc.).

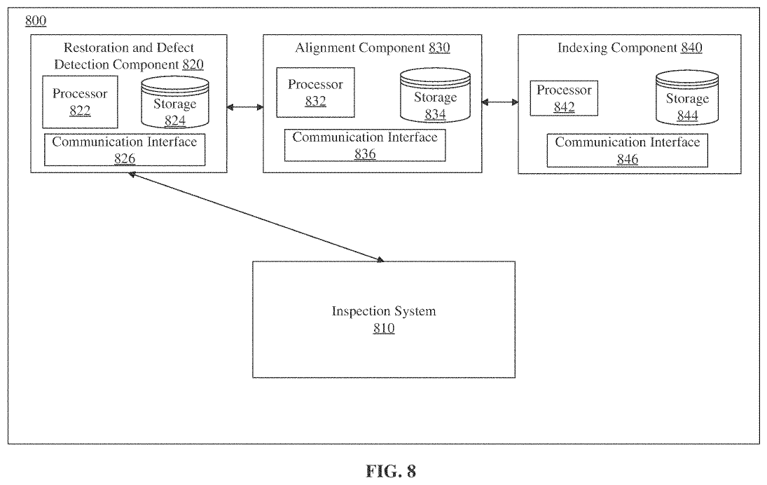

In some embodiments, a system (e.g., processor 822 of FIG. 8) may determine defect characteristics from inspection image 510 and generate an updated image 520 (e.g., defect-free SEM image) based on the determined defect characteristics and inspection image 510. In some embodiments, determining defect characteristics from inspection image 510 may include evaluating inspection image 510 to identify one or more defects and determining a set of one or more locations on inspection image 510 corresponding to the identified one or more defects. In some embodiments, a system may restore inspection image 510 to updated image 520 by mapping inspection image 510 to updated image 520 and applying the mapping to inspection image 510. In some embodiments, a system may restore inspection image 510 to updated image 520 by training a machine learning model to map inspection image 510 to updated image 520 and applying the machine learning model to inspection image 510. In some embodiments, a system may generate updated image 520 by removing or minimizing the identified one or more defects. In some embodiments, removing or minimizing the identified one or more defects may include masking one or more defects.

In some embodiments, defect-free characteristics may include “bright” features. Therefore, a system may generate updated image 520 by determining intensity levels for inspection image 510 and using the determined intensity levels and inspection image 510 to adjust the intensity levels of inspection image 510 to minimize one or more defects of inspection image 510 (e.g., adjusting the intensity levels of the defects in inspection image 510 to be defect-free bright features). In some embodiments, a system may generate updated image 520 by adjusting the intensity levels at the set of one or more locations on inspection image 510 corresponding to the identified one or more defects to minimize the identified one or more defects. Updated image 520 may include detected defects 522 (e.g., features at which the determined intensity levels of features were used, indicating electrical opens, electrical shorts, etc.).

In some embodiments, generating updated image 520 may include providing an indication of a set of one or more locations of updated image 520 that are associated with the set of one or more locations on inspection image 510 corresponding to the identified one or more defects (e.g., location of detected defect 522). In some embodiments, an indication may include metadata of the updated image or one or more characteristics of updated image 520.

In some embodiments, a system (e.g., processor 832 of FIG. 8) may align updated image 520 with a reference image (e.g., a template image). Using the alignment, a system may identify one or more locations (e.g., or one or more sets of one or more locations) of updated image 520 that are associated with the set of one or more locations on inspection image 510 corresponding to the identified one or more defects. For example, a system may use an alignment to identify one or more locations of updated image 520 at which a mapping was used to remove or minimize one or more defects. In some embodiments, a system may use an alignment to identify one or more locations of updated image 520 at which a machine learning model was applied.

The one or more identified locations or set of one or more locations of updated image 520 at which the determined defect characteristics were used to remove minimize one or more defects may correspond to the one or more defects on an inspected sample. For example, the set of one or more locations at which a mapping was used or the set of one or more locations at which a machine learning model was applied may correspond to one or more defects on an inspected sample.

Therefore, the system may identify one or more locations of defects on the sample. In some embodiments, one or more defects may include electrical opens, electrical shorts, necking, bridging, or edge placement errors.

Advantageously, even if a sample has many defects, updated image 520 may closely match or be consistent with a reference image (e.g., updated image 520 may be identical to the reference image) due to restoration of inspection image 510. Therefore, misalignment of updated image 520 and the reference image may be mitigated.

Moreover, a machine learning model may be trained during a plurality of restoration processes such that the accuracy of defect detection and restoration of inspection images increases, thereby increasing alignment between inspection images and reference images.

In some embodiments, a system (e.g., processor 842 of FIG. 8) may index the identified one or more locations of defects on the sample (e.g., bin or categorize locations or positions of defects on sample). For example, indexing the identified one or more locations of defects on a sample may include labeling a position of feature with a defect with respect to a sample (e.g., first via in the first row, fourteenth via in the third row, etc.).

In some embodiments, a system may use an indication of one or more sets of one or more locations to bin defects of the sample. For example, bins of defects may include a single defect (e.g., defect 512), a row of defects (e.g., row of defects 516), smaller defects, larger defects, etc. In some embodiments, the identified one or more locations (e.g., detected defect 522, detected row of defects 526) may be used to categorize defects as process defects or design defects. In some embodiments, types of defects may be categorized based on the identified one or more locations on the sample.

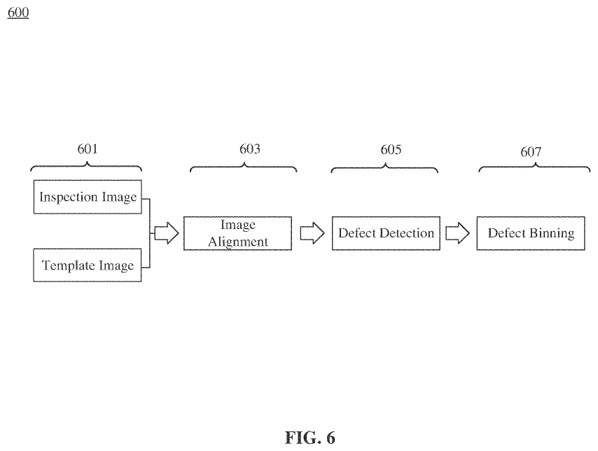

FIG. 6 illustrates a flowchart representing an exemplary method of image analysis. An image analysis process 600, as shown in FIG. 6, is often used to detect defects and identify the location of defects on a sample.

At step 601, a system may obtain an inspection image (e.g., a SEM image generated during inspection of a sample) and a template image. For example, a template image may be a defect-free SEM image of a sample. A template image may include one or more regions of a sample in a FOV.

At step 603, a system may perform a distortion correction on the inspection image and align the inspection image with the template image to identify the locations of one or more defects on an inspected sample.

At step 605, a system may detect one or more defects on an inspected sample by comparing the aligned images to a plurality of reference images (e.g., comparing an inspection image to two defect-free images of a sample during die-to-die inspection).

However, even after performing a distortion correction on the inspection image, image analysis using process 600 suffers from constraints. Because a sample may have many defects, the inspection image may differ greatly from a template image to which the inspection image is compared, resulting in misalignment of the inspection image and the template image.

Moreover, a plurality of reference images may be used to detect one or more defects under an assumption that defects occur randomly and rarely, thereby reducing the possibility that the reference images include the same defects as the inspection image. However, it is not uncommon for reference images to include the same defects as the inspection image. When reference images include defects (e.g., the same defects as the inspection image or other defects), a system may fail to identify real defects in the inspection image or the system may fail to use characteristics of the inspection image (e.g., physical features such as bridges) due to noisy data.

At step 607, a system may index the identified one or more locations of defects on the sample (e.g., bin or categorize locations or positions of defects on sample). For example, indexing the identified one or more locations of defects on a sample may include labeling a position of feature with a defect with respect to a sample (e.g., first via in the first row, fourteenth via in the third row, etc.).

Due to misalignment of the inspection image and the template image, systems using process 600 may not be able to accurately identify or index locations of defects on a sample (e.g., image analysis algorithms may fail during image alignment).

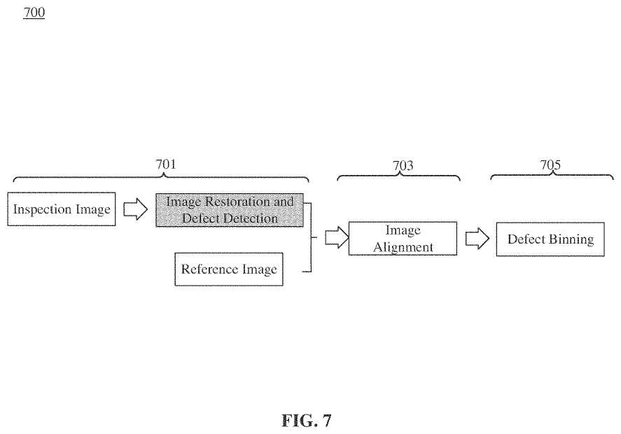

FIG. 7 illustrates a flowchart representing an exemplary method of image analysis, consistent with embodiments of the present disclosure. An image analysis process 700, as shown in FIG. 7, may be desirable to detect defects and identify the location of defects on a sample (e.g., sample of FIG. 2).

At step 701, a system (e.g., inspection system 810 of FIG. 8) may obtain an inspection image of a sample (e.g., a SEM image generated during inspection of a sample). A system (e.g., processor 822 of FIG. 8) may detect one or more defects in the inspection image (e.g., inspection image 510 of FIG. 5) by detecting regions of the inspection image to be restored (e.g., defect 512 of FIG. 5). In some embodiments, determining defect characteristics from the inspection image may include evaluating the inspection image to identify one or more defects and determining a set of one or more locations on the inspection image corresponding to the identified one or more defects. A system may restore the inspection image to a defect-free image (e.g., updated image 520 of FIG. 5) by determining defect characteristics from the inspection image and generating an updated image using the determined defect characteristics and the inspection image. For example, generating the updated image may include adjusting the inspection image to minimize or remove one or more defects on the inspection image.

In some embodiments, a system may restore the inspection image to a defect-free image by mapping the inspection image to a defect-free image and applying the mapping to the inspection image. In some embodiments, a system may restore the inspection image to a defect-free image by training a machine learning model to map the inspection image to a defect-free image and applying the machine learning model to the inspection image. In some embodiments, a system may generate the updated image by removing or minimizing the identified one or more defects. In some embodiments, removing or minimizing the identified one or more defects may include masking one or more defects.

In some embodiments, defect characteristics may include defect intensity levels (e.g., levels of “bright” or “dark” grey levels of voltage contrast images associated with defect-free features of a sample) of an image. For example, generating the updated image may include adjusting the intensity levels of the inspection image to minimize a defect on the inspection image (e.g., adjusting the intensity levels of the defects in the inspection image to be defect-free bright features). In some embodiments, a system may the generate updated image by adjusting the intensity levels at the set of one or more locations on the inspection image corresponding to the identified one or more defects to minimize the identified one or more defects. In some embodiments, defect characteristics may include line-edge roughness, line-width roughness, local critical dimension uniformity, holes, or broken lines associated with a defect-free features of a sample. In some embodiments, defect characteristics may include characteristics of features of a sample without defects such as necking, bridging, or edge placement errors.

In some embodiments, generating the updated image may include providing an indication of a set of one or more locations of the updated image that are associated with the set of one or more locations on the inspection image corresponding to the identified one or more defects. In some embodiments, an indication may include metadata of the updated image or one or more characteristics of the updated image.

Advantageously, defect detection and image restoration may occur in a single module (e.g., restoration and defect detection component 820 of FIG. 8) since only one defect-free reference image is needed for defect detection and image restoration. Moreover, since the reference image is defect-free, a system may identify real defects in the inspection image and use characteristics of the inspection image during image analysis.

At step 703, a system (e.g., processor 832 of FIG. 8) may align the updated image (e.g., updated image 520 of FIG. 5) with a reference image (e.g., a template image). For example, a system may align a mapped inspection image with a reference image. Using the alignment, a system may identify one or more locations (e.g., or one or more sets of one or more locations) of the updated image at which determined defect characteristics were used to minimize or remove one or more defects. For example, a system may use an alignment to identify one or more locations of the updated image at which a mapping was used. In some embodiments, a system may use an alignment to identify one or more locations of the updated image at which a machine learning model was applied.

For example, a reference image may be a defect-free image of a sample. In some embodiments, a reference image may include one or more regions of a sample in a FOV. In some embodiments, a reference image may include user-defined data (e.g., locations of features on a sample). In some embodiments, a reference image may be a golden image (e.g., an actual “perfect” defect-free image or a machine learning generated image). In some embodiments, a reference image may be rendered from layout design data.

For example, a layout design of a sample may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a layout design may correspond to a FOV of an inspection system (e.g., a FOV of inspection system 810 of FIG. 8 may include one or more layout structures of a layout design). In some embodiments, a layout design may be selected based on inspected samples (e.g., based on layouts that have been identified on a sample).

The one or more identified locations or set of one or more locations of the updated image at which the determined defect characteristics were used may correspond to the one or more defects on an inspected sample. For example, the set of one or more locations at which a mapping was used or the set of one or more locations at which a machine learning model was applied may correspond to one or more defects on an inspected sample.

Therefore, the system may identify one or more locations of defects on the sample. In some embodiments, one or more defects may include electrical opens, electrical shorts, necking, bridging, edge placement errors, holes, broken lines, etc.

Advantageously, even if a sample has many defects, the updated image may closely match or be consistent with a reference image (e.g., the updated image may be identical to the reference image) due to restoration of the inspection image. Therefore, misalignment of the restored inspection image and the reference image may be mitigated.

Moreover, a machine learning model may be trained during a plurality of restoration processes such that the accuracy of defect detection and restoration of inspection images increases, thereby increasing alignment between inspection images and reference images.

At step 705, a system (e.g., processor 842 of FIG. 8) may index the identified one or more locations of defects on the sample (e.g., bin or categorize locations or positions of defects on sample). For example, indexing the identified one or more locations of defects on a sample may include labeling a position of feature with a defect with respect to a sample (e.g., first via in the first row, fourteenth via in the third row, etc.).

In some embodiments, a system may use an indication of one or more sets of one or more locations to bin defects of the sample. For example, bins of defects may include a single defect (e.g., defect 512 of FIG. 5), a row of defects (e.g., row of defects 516 of FIG. 5), smaller defects, larger defects, etc. In some embodiments, the identified one or more locations (e.g., detected defect 522 of FIG. 5, detected row of defects 526 of FIG. 5) may be used to bin or categorize defects as process defects or design defects. In some embodiments, types of defects may be binned or categorized based on the identified one or more locations on the sample.

Advantageously, due to the alignment of the restored inspection image and the template image, the system may accurately identify and index locations of defects on a sample.

FIG. 8 is a schematic diagram of a system for defect detection and defect location identification, consistent with embodiments of the present disclosure. System 800 may include an inspection system 810, a restoration and defect detection component 820, an alignment component 830, and an indexing component 840. Inspection system 810, restoration and defect detection component 820, alignment component 830, and indexing component 840 may be electrically coupled (directly or indirectly) to each other, either physically (e.g., by a cable) or remotely. Inspection system 810 may be the system described with respect to FIGS. 1 and 2, used to acquire images of a wafer (see, e.g., sample 208 of FIG. 2). In some embodiments, components of system 800 may be implemented as one or more servers (e.g., where each server includes its own processor). In some embodiments, components of system 800 may be implemented as software that may pull data from one or more databases of system 800. In some embodiments, system 800 may include one server or a plurality of servers. In some embodiments, system 800 may include one or more modules that are implemented by a controller (e.g., controller 109 of FIG. 1, controller 109 of FIG. 2).

Inspection system 810 may transmit data including inspection images of a sample (e.g., sample 208 of FIG. 2) to restoration and defect detection component 820.

Restoration and defect detection component 820 may include a processor 822 and a storage 824. Component 820 may also include a communication interface 826 to send data to alignment component 830. Processor 822 may be configured to detect one or more defects in an inspection image (e.g., inspection image 510 of FIG. 5) by detecting regions of the inspection image that need restoration (e.g., defect 512 of FIG. 5, row of defects 516 of FIG. 5). In some embodiments, processor 822 may be configured to detect one or more defects in an inspection image by evaluating the inspection image to identify one or more defects and determining a set of one or more locations on the inspection image corresponding to the identified one or more defects. Processor 822 may be configured to restore the inspection image to a defect-free image (e.g., updated image 520 of FIG. 5) by determining defect characteristics from the inspection image and generating an updated image (e.g., updated image 520 of FIG. 5) using the determined defect characteristics and the inspection image. For example, generating the updated image may include adjusting the inspection image to minimize or remove one or more defects on the inspection image.

In some embodiments, processor 822 may be configured to restore the inspection image to a defect-free image by mapping the inspection image to a defect-free image and applying the mapping to the inspection image. In some embodiments, processor 822 may be configured to restore the inspection image to a defect-free image by training a machine learning model to map the inspection image to a defect-free image and applying the machine learning model to the inspection image. In some embodiments, processor 822 may generate the updated image by removing or minimizing the identified one or more defects. In some embodiments, removing or minimizing the identified one or more defects may include masking one or more defects.

In some embodiments, defect characteristics may include defect intensity levels (e.g., levels of “bright” or “dark” grey levels of voltage contrast images associated with defect-free features of a sample) of an image. For example, generating the updated image may include adjusting the intensity levels of the inspection image to minimize a defect on the inspection image (e.g., adjusting the intensity levels of the defects in the inspection image to be defect-free bright features). In some embodiments, processor 822 may generate an updated image by adjusting the intensity levels at the set of one or more locations on an inspection image corresponding to the identified one or more defects to minimize the identified one or more defects. In some embodiments, defect characteristics may include line-edge roughness, line-width roughness, local critical dimension uniformity, holes, broken lines associated with a defect features of a sample. In some embodiments, defect-free characteristics may include characteristics of features of a sample without defects such as necking, bridging, or edge placement errors.

In some embodiments, generating the updated image may include providing an indication of a set of one or more locations of the updated image that are associated with the set of one or more locations on an inspection image corresponding to the identified one or more defects. In some embodiments, an indication may include metadata of the updated image or one or more characteristics of the updated image.

Advantageously, defect detection and image restoration may occur in a single module (e.g., component 820) since only one defect-free reference image is needed for defect detection and image restoration. Moreover, since the reference image is defect-free, processor 822 may be configured to identify real defects in the inspection image and use characteristics of the inspection image during image analysis.

Component 820 may transmit data including restored inspection images to alignment component 830.

Alignment component 830 may include a processor 832 and a storage 834. Alignment component 830 may also include a communication interface 826 to send data to indexing component 840. Processor 832 may be configured to align the updated image (e.g., updated image 520 of FIG. 5) with a reference image. For example, processor 832 may be configured to align a mapped inspection image with a reference image. Using the alignment, processor 832 may be configured to identify one or more locations of the updated image at which the determined defect characteristics were used to minimize or remove one or more defects. For example, processor 832 may be configured to use an alignment to identify one or more locations of the updated image at which a mapping was applied. In some embodiments, processor 832 may be configured to use an alignment to identify one or more locations of the updated image at which a machine learning model was applied.

For example, a reference image may be a defect-free image of a sample. In some embodiments, a reference image may include one or more regions of a sample in a FOV. In some embodiments, a reference image may include user-defined data (e.g., locations of features on a sample). In some embodiments, a reference image may be a golden image (e.g., an actual “perfect” defect-free image or a machine learning generated image). In some embodiments, a reference image may be rendered from layout design data.

For example, a layout design of a sample may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a layout design may correspond to a FOV of an inspection system (e.g., a FOV of inspection system 810 may include one or more layout structures of a layout design). In some embodiments, a layout design may be selected based on inspected samples (e.g., based on layouts that have been identified on a sample).

The one or more identified locations or set of one or more locations of the updated image at which the determined defect characteristics were used may correspond to the one or more defects on an inspected sample. For example, the set of one or more locations at which a mapping was applied or the set of one or more locations at which a machine learning model was applied may correspond to one or more defects on an inspected sample.

Therefore, the system may identify one or more locations of defects on the sample. In some embodiments, one or more defects may include electrical opens, electrical shorts, necking, bridging, edge placement errors, holes, broken lines, etc.

Advantageously, even if a sample has many defects, the updated image may closely match or be consistent with a reference image (e.g., the updated image may be identical to the reference image) due to restoration of the inspection image. Therefore, misalignment of the restored inspection image and the reference image may be mitigated.

Moreover, a machine learning model may be trained during a plurality of restoration processes such that the accuracy of defect detection and restoration of inspection images increases, thereby increasing alignment between inspection images and reference images.

Alignment component 830 may transmit data including identified locations of the inspection image at which the inspection image was restored to indexing component 840.

Indexing component 840 may include a processor 842 and a storage 844. Indexing component 840 may also include a communication interface 846 to receive data from alignment component 830. Processor 842 may be configured to index the identified one or more locations of defects on the sample (e.g., bin or categorize locations or positions of defects on sample). For example, indexing the identified one or more locations of defects on a sample may include labeling a position of feature with a defect with respect to a sample (e.g., first via in the first row, fourteenth via in the third row, etc.).

In some embodiments, a system may use an indication of one or more sets of one or more locations to bin defects of the sample. For example, bins of defects may include a single defect (defect 512 of FIG. 5), a row of defects (e.g., row of defects 516 of FIG. 5), smaller defects, larger defects. In some embodiments, the identified one or more locations (e.g., detected defect 522 of FIG. 5, detected row of defects 526 of FIG. 5) may be used to categorize defects as process defects or design defects. In some embodiments, types of defects may be categorized based on the identified one or more locations on the sample.

Advantageously, due to the alignment of the restored inspection image and the template image, processor 842 may be configured to accurately identify and index locations of defects on a sample.

A non-transitory computer readable medium may be provided that stores instructions for a processor of a controller (e.g., controller 109 of FIG. 1) for controlling the electron beam tool, consistent with embodiments in the present disclosure. For example, instructions may include obtaining an inspection image of a sample, determining defect characteristics from the image, generating an updated image by using the determined defect characteristics and the image, and aligning the updated image with a reference image (see, e.g., FIG. 7). Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method of image analysis, comprising:
obtaining an image of a sample;
determining defect characteristics from the image;
generating an updated image based on the determined defect characteristics and the image; and
aligning the updated image with a reference image.

2. The method of clause 1, wherein determining defect characteristics from the image comprises:
evaluating the image of the sample to identify any one or more defects; and
determining a set of one or more locations on the image corresponding to the identified one or more defects.

3. The method of clause 2, wherein generating the updated image comprises:
providing an indication of a set of one or more locations on the updated image that are associated with the set of one or more locations on the image corresponding to the identified one or more defects.

4. The method of any one of clauses 2-3, wherein generating the updated image comprises:
removing or minimizing the identified one or more defects.

5. The method of any one of clauses 3-4, further comprising binning the one or more defects based on the indication of the set of one or more locations.

6. The method of any one of clauses 3-5, wherein the indication comprises any one of metadata of the updated image or a characteristic of the updated image.

7. The method of any one of clauses 1-6, wherein generating the updated image further comprises adjusting the image to minimize a defect on the image.

8. The method of any one of clauses 1-7, wherein the determined defect characteristics comprise intensity levels from the image.

9. The method of clause 8, wherein the intensity levels from the image correspond to grey levels that indicate voltage contrast.

10. The method of any one of clauses 8-9, wherein generating the updated image further comprises adjusting the intensity levels at a set of one or more locations on the image corresponding to identified one or more defects to remove or minimize the identified one or more defects.

11. The method of any one of clauses 2-10, wherein the one or more defects indicate any one of an electrical short or an electrical open.

12. The method of any one of clauses 2-11, wherein the one or more defects indicate any one of necking, bridging, edge placement error, hole, or a broken line.

13. The method of any one of clauses 1-12, wherein the reference image is based on layout data.

14. The method of any one of clauses 1-13, wherein the reference image comprises a golden image.

15. A non-transitory computer readable medium that stores a set of instructions that is executable by at least one processor of a computing device to cause the computing device to perform a method for image analysis, the method comprising:
obtaining an image of a sample;
determining defect characteristics from the image;
generating an updated image based on the determined defect characteristics and the image; and
aligning the updated image with a reference image.

16. The non-transitory computer readable medium of clause 15, wherein the set of instructions that is executable by at least one processor of a computing device to cause the computing device to further perform determining defect characteristics from the image by:
evaluating the image of the sample to identify any one or more defects; and
determining a set of one or more locations on the image corresponding to the identified one or more defects.

17. The non-transitory computer readable medium of clause 16, wherein the set of instructions that is executable by at least one processor of a computing device to cause the computing device to further perform:
providing an indication of a set of one or more locations on the updated image that are associated with the set of one or more locations on the image corresponding to the identified one or more defects.

18. The non-transitory computer readable medium of any one of clauses 16-17, wherein generating the updated image comprises:
removing or minimizing the identified one or more defects.

19. The non-transitory computer readable medium of any one of clauses 17-18, wherein the set of instructions that is executable by at least one processor of a computing device to cause the computing device to further perform:
binning the one or more defects based on the indication of the set of one or more locations.

20. The non-transitory computer readable medium of any one of clauses 17-19, wherein the indication comprises any one of metadata of the updated image or a characteristic of the updated image.

21. The non-transitory computer readable medium of any one of clauses 15-20, wherein generating the updated image further comprises adjusting the image to minimize a defect on the image.

22. The non-transitory computer readable medium of any one of clauses 15-21, wherein the determined defect characteristics comprise intensity levels from the image.

23. The non-transitory computer readable medium of clause 22, wherein the intensity levels from the image correspond to grey levels that indicate voltage contrast.

24. The non-transitory computer readable medium of any one of clauses 22-23, wherein generating the updated image further comprises adjusting the intensity levels at a set of one or more locations on the image corresponding to identified one or more defects to remove or minimize the identified one or more defects.

25. The non-transitory computer readable medium of any one of clauses 16-24, wherein the one or more defects indicate any one of an electrical short or an electrical open.

26. The non-transitory computer readable medium of any one of clauses 16-25, wherein the one or more defects indicate any one of necking, bridging, edge placement error, hole or a broken line.

27. The non-transitory computer readable medium of any one of clauses 15-26, wherein the reference image is based on layout data.

28. The non-transitory computer readable medium of any one of clauses 15-27, wherein the reference image comprises a golden image.

29. A system for image analysis, comprising:
a controller including circuitry configured to cause the system to perform:
obtaining an image of a sample;
determining defect characteristics from the image;
generating an updated image based on the determined defect characteristics and the image; and
aligning the updated image with a reference image.

30. The system of clause 29, wherein determining defect characteristics from the image comprises:
evaluating the image of the sample to identify any one or more defects; and
determining a set of one or more locations on the image corresponding to the identified one or more defects.

31. The system of clause 30, wherein the controller includes circuitry configured to cause the system to further perform:
providing an indication of a set of one or more locations on the updated image that are associated with the set of one or more locations on the image corresponding to the identified one or more defects.

32. The system of any one of clauses 30-31, wherein generating the updated image comprises:
removing or minimizing the identified one or more defects.

33. The system of any one of clauses 31-32, wherein the controller includes circuitry configured to cause the system to further perform comprising binning the one or more defects based on the indication of the set of one or more locations.

34. The system of any one of clauses 31-33, wherein the indication comprises any one of metadata of the updated image or a characteristic of the updated image.

35. The system of any one of clauses 29-34, wherein generating the updated image further comprises adjusting the image to minimize a defect on the image.

36. The system of any one of clauses 29-35, wherein the determined defect characteristics comprise intensity levels from the image.

37. The system of clause 36, wherein the intensity levels from the image correspond to grey levels that indicate voltage contrast.

38. The system of any one of clauses 36-37, wherein generating the updated image further comprises adjusting the intensity levels at a set of one or more locations on the image corresponding to identified one or more defects to remove or minimize the identified one or more defects.

39. The system of any one of clauses 30-38, wherein the one or more defects indicate any one of an electrical short or an electrical open.

40. The system of any one of clauses 30-39, wherein the one or more defects indicate any one of necking, bridging, edge placement error, hole or a broken line.

41. The system of any one of clauses 29-40, wherein the reference image is based on layout data.

42. The system of any one of clauses 29-41, wherein the reference image comprises a golden image.

43. A method of image analysis, comprising:
obtaining an image of a sample;
mapping the image to a defect-free image;
generating an updated image based on the mapping and the image; and
aligning the updated image with a reference image.

44. The method of clause 43, wherein mapping the image to the defect-free image comprises:
evaluating the image of the sample to identify any one or more defects; and
determining a set of one or more locations on the image corresponding to the identified one or more defects.

45. The method of clause 44, wherein generating the updated image comprises:
providing an indication of a set of one or more locations on the updated image that are associated with the set of one or more locations on the image corresponding to the identified one or more defects.

46. The method of any one of clauses 44-45, wherein generating the updated image comprises:
removing or minimizing the identified one or more defects.

47. The method of any one of clauses 45-46, further comprising binning the one or more defects based on the indication of the set of one or more locations.

48. The method of any one of clauses 45-47, wherein the indication comprises any one of metadata of the updated image or a characteristic of the updated image.

49. The method of any one of clauses 43-48, wherein generating the updated image further comprises adjusting the image to minimize a defect on the image.

50. The method of any one of clauses 43-49, wherein the mapping comprises intensity levels from the image.

51. The method of clause 50, wherein the intensity levels from the image correspond to grey levels that indicate voltage contrast.

52. The method of any one of clauses 50-51, wherein generating the updated image further comprises adjusting the intensity levels at a set of one or more locations on the image corresponding to identified one or more defects to remove or minimize the identified one or more defects.

53. The method of any one of clauses 44-52, wherein the one or more defects indicate any one of an electrical short or an electrical open.

54. The method of any one of clauses 44-53, wherein the one or more defects indicate any one of necking, bridging, edge placement error, hole, or a broken line.

55. The method of any one of clauses 43-54, wherein the reference image is based on layout data.

56. The method of any one of clauses 43-55, wherein the reference image comprises a golden image.

57. A non-transitory computer readable medium that stores a set of instructions that is executable by at least one processor of a computing device to cause the computing device to perform a method for image analysis, the method comprising:
obtaining an image of a sample;
mapping the image to a defect-free image;
generating an updated image based on the mapping and the image; and
aligning the updated image with a reference image.

58. The non-transitory computer readable medium of clause 57, wherein the set of instructions that is executable by at least one processor of a computing device to cause the computing device to further perform mapping the image to the defect-free image by:
evaluating the image of the sample to identify any one or more defects; and
determining a set of one or more locations on the image corresponding to the identified one or more defects.

59. The non-transitory computer readable medium of clause 58, wherein the set of instructions that is executable by at least one processor of a computing device to cause the computing device to further perform:
providing an indication of a set of one or more locations on the updated image that are associated with the set of one or more locations on the image corresponding to the identified one or more defects.

60. The non-transitory computer readable medium of any one of clauses 58-59, wherein generating the updated image comprises:
removing or minimizing the identified one or more defects.

61. The non-transitory computer readable medium of any one of clauses 59-60, wherein the set of instructions that is executable by at least one processor of a computing device to cause the computing device to further perform:
binning the one or more defects based on the indication of the set of one or more locations.

62. The non-transitory computer readable medium of any one of clauses 59-61, wherein the indication comprises any one of metadata of the updated image or a characteristic of the updated image.

63. The non-transitory computer readable medium of any one of clauses 57-62, wherein generating the updated image further comprises adjusting the image to minimize a defect on the image.

64. The non-transitory computer readable medium of any one of clauses 57-63, wherein the mapping comprises intensity levels from the image.

65. The non-transitory computer readable medium of clause 64, wherein the intensity levels from the image correspond to grey levels that indicate voltage contrast.

66. The non-transitory computer readable medium of any one of clauses 64-65, wherein generating the updated image further comprises adjusting the intensity levels at a set of one or more locations on the image corresponding to identified one or more defects to remove or minimize the identified one or more defects.

67. The non-transitory computer readable medium of any one of clauses 58-66, wherein the one or more defects indicate any one of an electrical short or an electrical open.

68. The non-transitory computer readable medium of any one of clauses 58-67, wherein the one or more defects indicate any one of necking, bridging, edge placement error, hole, or a broken line.

69. The non-transitory computer readable medium of any one of clauses 57-68, wherein the reference image is based on layout data.

70. The non-transitory computer readable medium of any one of clauses 57-69, wherein the reference image comprises a golden image.

71. A system for image analysis, comprising:
a controller including circuitry configured to cause the system to perform:
obtaining an image of a sample;
mapping the image to a defect-free image;
generating an updated image based on the mapping and the image; and
aligning the updated image with a reference image.

72. The system of clause 71, wherein mapping the image to the defect-free image comprises:
evaluating the image of the sample to identify any one or more defects; and
determining a set of one or more locations on the image corresponding to the identified one or more defects.

73. The system of clause 72, wherein the controller includes circuitry configured to cause the system to further perform:
providing an indication of a set of one or more locations on the updated image that are associated with the set of one or more locations on the image corresponding to the identified one or more defects.

74. The system of any one of clauses 72-73, wherein generating the updated image comprises:
removing or minimizing the identified one or more defects.

75. The system of any one of clauses 73-74, wherein the controller includes circuitry configured to cause the system to further perform comprising binning the one or more defects based on the indication of the set of one or more locations.

76. The system of any one of clauses 73-75, wherein the indication comprises any one of metadata of the updated image or a characteristic of the updated image.

77. The system of any one of clauses 71-76, wherein generating the updated image further comprises adjusting the image to minimize a defect on the image.

78. The system of any one of clauses 71-77, wherein the mapping comprises intensity levels from the image.

79. The system of clause 78, wherein the intensity levels from the image correspond to grey levels that indicate voltage contrast.

80. The system of any one of clauses 78-79, wherein generating the updated image further comprises adjusting the intensity levels at a set of one or more locations on the image corresponding to identified one or more defects to remove or minimize the identified one or more defects.

81. The system of any one of clauses 72-80, wherein the one or more defects indicate any one of an electrical short or an electrical open.

82. The system of any one of clauses 72-81, wherein the one or more defects indicate any one of necking, bridging, edge placement error, hole, or a broken line.

83. The system of any one of clauses 71-82, wherein the reference image is based on layout data.

84. The system of any one of clauses 71-83, wherein the reference image comprises a golden image.

85. A method of image analysis, comprising:
obtaining an image of a sample;
training a machine learning model to map the image to a defect-free image;
generating an updated image by applying the machine learning model to the image; and
aligning the updated image with a reference image.

86. The method of clause 85, wherein mapping the image to the defect-free image comprises:
evaluating the image of the sample to identify any one or more defects; and
determining a set of one or more locations on the image corresponding to the identified one or more defects.

87. The method of clause 86, wherein generating the updated image comprises:
providing an indication of a set of one or more locations on the updated image that are associated with the set of one or more locations on the image corresponding to the identified one or more defects.

88. The method of any one of clauses 86-87, wherein generating the updated image comprises: removing or minimizing the identified one or more defects.

89. The method of any one of clauses 87-88, further comprising binning the one or more defects based on the indication of the set of one or more locations.

90. The method of any one of clauses 87-89, wherein the indication comprises any one of metadata of the updated image or a characteristic of the updated image.

91. The method of any one of clauses 85-90, wherein generating the updated image further comprises adjusting the image to minimize a defect on the image.

92. The method of any one of clauses 85-91, wherein the mapping comprises intensity levels from the image.

93. The method of clause 92, wherein the intensity levels from the image correspond to grey levels that indicate voltage contrast.

94. The method of any one of clauses 92-93, wherein generating the updated image further comprises adjusting the intensity levels at a set of one or more locations on the image corresponding to identified one or more defects to remove or minimize the identified one or more defects.

95. The method of any one of clauses 86-94, wherein the one or more defects indicate any one of an electrical short or an electrical open.

96. The method of any one of clauses 86-95, wherein the one or more defects indicate any one of necking, bridging, edge placement error, hole or a broken line.

97. The method of any one of clauses 85-96, wherein the reference image is based on layout data.

98. The method of any one of clauses 85-97, wherein the reference image comprises a golden image.

99. A method of image analysis, comprising:
obtaining an image of a sample;
generating an updated image by applying a machine learning model to the image, wherein the machine learning model maps the image to a defect-free image; and
aligning the updated image with a reference image.

100. The method of clause 99, wherein mapping the image to the defect-free image comprises:
evaluating the image of the sample to identify any one or more defects; and
determining a set of one or more locations on the image corresponding to the identified one or more defects.

101. The method of clause 100, wherein generating the updated image comprises:
providing an indication of a set of one or more locations on the updated image that are associated with the set of one or more locations on the image corresponding to the identified one or more defects.

102. The method of any one of clauses 100-101, wherein generating the updated image comprises:
removing or minimizing the identified one or more defects.

103. The method of any one of clauses 101-102, further comprising binning the one or more defects based on the indication of the set of one or more locations.

104. The method of any one of clauses 101-103, wherein the indication comprises any one of metadata of the updated image or a characteristic of the updated image.

105. The method of any one of clauses 99-104, wherein generating the updated image further comprises adjusting the image to minimize a defect on the image.

106. The method of any one of clauses 99-105, wherein the mapping comprises intensity levels from the image.

107. The method of clause 106, wherein the intensity levels from the image correspond to grey levels that indicate voltage contrast.

108. The method of any one of clauses 106-107, wherein generating the updated image further comprises adjusting the intensity levels at a set of one or more locations on the image corresponding to identified one or more defects to remove or minimize the identified one or more defects.

109. The method of any one of clauses 100-108, wherein the one or more defects indicate any one of an electrical short or an electrical open.

110. The method of any one of clauses 100-109, wherein the one or more defects indicate any one of necking, bridging, edge placement error, hole, or a broken line.

111. The method of any one of clauses 99-110, wherein the reference image is based on layout data.

112. The method of any one of clauses 99-111, wherein the reference image comprises a golden image.

It will be appreciated that the embodiments of the present disclosure are not limited to the exact construction that has been described above and illustrated in the accompanying drawings, and that various modifications and changes may be made without departing from the scope thereof.

1. A system for image analysis, comprising:
a controller including circuitry configured to cause the system to perform:
obtaining an image of a sample;
determining defect characteristics from the image;
generating an updated image based on the determined defect characteristics and the image; and
aligning the updated image with a reference image.

2. The system of claim 1, wherein determining defect characteristics from the image comprises:
evaluating the image of the sample to identify any one or more defects; and
determining a set of one or more locations on the image corresponding to the one or more identified defects.

3. The system of claim 2, wherein the controller includes circuitry configured to cause the system to further perform:
providing an indication of a set of one or more locations on the updated image that are associated with the set of one or more locations on the image corresponding to the identified one or more defects.

4. The system of claim 2, wherein generating the updated image comprises:
removing or minimizing the identified one or more defects.

5. The system of claim 3, wherein the controller includes circuitry configured to cause the system to further perform binning the one or more defects based on the indication of the set of one or more locations.

6. The system of claim 3, wherein the indication comprises any one of metadata of the updated image or a characteristic of the updated image.

7. The system of claim 1, wherein generating the updated image further comprises adjusting the image to minimize a defect on the image.

8. The system of claim 1, wherein the determined defect characteristics comprise intensity levels from the image.

9. The system of claim 8, wherein the intensity levels from the image correspond to grey levels that indicate voltage contrast.

10. The system of claim 8, wherein generating the updated image further comprises adjusting the intensity levels at a set of one or more locations on the image corresponding to one or more identified defects to remove or minimize the one or more identified defects.

11. The system of claim 2, wherein the one or more defects indicate any one of an electrical short or an electrical open.

12. The system of claim 2, wherein the one or more defects indicate any one of necking, bridging, edge placement error, hole or a broken line.

13. The system of claim 1, wherein the reference image is based on layout data.

14. The system of claim 1, wherein the reference image comprises a golden image.

15. A non-transitory computer readable medium that stores a set of instructions that is executable by at least one processor of a computing device to cause the computing device to perform operations for image analysis, the operations comprising:
obtaining an image of a sample;
mapping the image to a defect-free image;
generating an updated image based on the mapping and the image; and
aligning the updated image with a reference image.

16. The non-transitory computer readable medium of claim 15, wherein the operations further comprise mapping the image to the defect-free image by:
evaluating the image of the sample to identify any one or more defects; and
determining a set of one or more locations on the image corresponding to the identified one or more defects.

17. The non-transitory computer readable medium of claim 16, wherein the operations further comprise:
providing an indication of a set of one or more locations on the updated image that are associated with the set of one or more locations on the image corresponding to the identified one or more defects.

18. The non-transitory computer readable medium of any one of claim 17, wherein generating the updated image comprises:
removing or minimizing the identified one or more defects.

19. The non-transitory computer readable medium of any one of claim 17, wherein the operations further comprise:
binning the one or more defects based on the indication of the set of one or more locations.

20. The non-transitory computer readable medium of any one of claim 17, wherein the indication comprises any one of metadata of the updated image or a characteristic of the updated image.
